(19) United States
(12) Patent Application Publication
(10) Pub. No.: US 2023/0162977 A1
(43) Pub. Date: May 25, 2023

(54) SUBSTRATE PROCESSING METHOD AND SUBSTRATE PROCESSING APPARATUS

(71) Applicant: Tokyo Electron Limited, Tokyo (JP)

(72) Inventors: Hiroki MURAKAMI, Nirasaki-shi, Yamanashi (JP); Kazuo YABE, Nirasaki-shi, Yamanashi (JP)

(21) Appl. No.: 17/910,979

(22) PCT Filed: Mar. 5, 2021
(86) PCT No.: PCT/JP2021/008802

§ 371 Date: Sep. 12, 2022

(30) Foreign Application Priority Data
Mar. 17, 2020 (JP) 2020-046631

(51) Int. Cl. H01L 21/02; C23C 16/04

(52) U.S. Cl. CPC H01L 21/0262; C23C 16/045; H01L 21/02381; H01L 21/02403

(57) ABSTRACT

Provided are a substrate processing method and a substrate processing apparatus, wherein a silicon oxide film is favorably embedded. The substrate processing method includes forming a silicon oxide film by repeating a cycle a plurality of times, the cycle including: forming an adsorption layer by supplying a silicon-containing gas to a substrate having a depression formed therein and causing the silicon-containing gas to be adsorbed on the substrate; etching at least a portion of the adsorption layer by supplying a shape control gas to the substrate; and supplying an oxygen-containing gas to the substrate and causing the oxygen-containing gas to react with the adsorption layer, wherein the temperature of the substrate is 400° C. or lower.

### TECHNICAL FIELD

The present disclosure relates to a substrate processing method and a substrate processing apparatus.

### BACKGROUND

For example, a substrate processing apparatus that embeds a film in a substrate having irregularities formed therein is known.

Patent Document 1 discloses a method for forming a silicon-containing film with which a silicon-containing film is filled in a depression formed on a surface of a substrate, the method including a first film-forming cycle including a first silicon adsorption step of supplying a silicon-containing gas to the substrate and causing the silicon-containing gas to be adsorbed in the depression, a silicon etching step of supplying an etching gas to the substrate and etching a portion of a silicon component of the silicon-containing gas adsorbed in the depression, and a first silicon-containing film deposition step of supplying a reaction gas that reacts with the silicon component to the substrate, causing the reaction gas to react with the silicon component remaining adsorbed in the depression after etching to produce a reaction product, and depositing a silicon-containing film in the depression.

### PRIOR ART DOCUMENT

### Patent Document

Patent Document 1: Japanese laid-open publication No. 2017-11136

The present disclosure provides some embodiments of a substrate processing method and a substrate processing apparatus, wherein a silicon oxide film is favorably embedded.

### SUMMARY

According to an embodiment of the present disclosure, there is provided a substrate processing method, including forming a silicon oxide film by repeating a cycle a plurality of times, the cycle including: forming an adsorption layer by supplying a silicon-containing gas to a substrate having a depression formed therein and causing the silicon-containing gas to be adsorbed on the substrate; etching at least a portion of the adsorption layer by supplying a shape control gas to the substrate; and supplying an oxygen-containing gas to the substrate and causing the oxygen-containing gas to react with the adsorption layer, wherein a temperature of the substrate is 400° C. or lower.

According to some embodiments of the present disclosure, it is possible to provide a substrate processing method and a substrate processing apparatus, wherein a silicon oxide film is favorably embedded.

### BRIEF DESCRIPTION OF DRAWINGS

FIG. 1 is a schematic diagram illustrating a configuration example of a substrate processing apparatus.

FIG. 2 is an example of a time chart showing a film-forming process of a SiO₂ film by a substrate processing apparatus.

FIG. 3A is an example of a schematic cross-sectional view of a substrate W in each step of the film-forming process.

FIG. 3B is an example of a schematic cross-sectional view of the substrate W in each step of the film-forming process.

FIG. 3C is an example of a schematic cross-sectional view of the substrate W in each step of the film-forming process.

FIG. 4 is a cross-sectional view illustrating a relationship between a process temperature and a film shape of the SiO₂ film.

FIG. 5 is a flowchart showing an example of embedding process of the SiO₂ film.

FIG. 6A is a schematic diagram describing another embedding method of the SiO₂ film.

FIG. 6B is a schematic diagram describing another embedding method of the SiO₂ film.

FIG. 6C is a schematic diagram describing another embedding method of the SiO₂ film.

### DETAILED DESCRIPTION

Hereinafter, embodiments in which the present disclosure are implemented will be described with reference to the drawings. In each figure, the same components may be designated with the same reference numerals, and duplicated descriptions may be omitted.

### Substrate Processing Apparatus

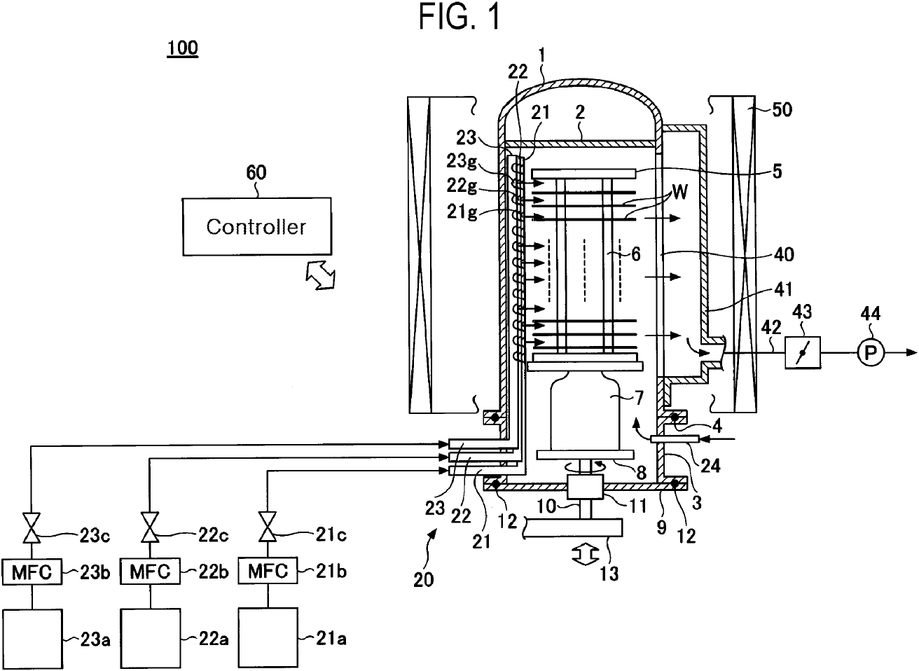

A substrate processing apparatus 100 in accordance with the present embodiment will be described using FIG. 1. FIG. 1 is a schematic diagram illustrating a configuration example of a substrate processing apparatus 100. Further, the substrate processing apparatus 100 is a film-forming apparatus that forms a SiO₂ film on a substrate W having a depression such as a trench, and embeds the SiO₂ film in the depression.

The substrate processing apparatus 100 includes a process container 1 formed in a shape of a cylindrical body having a ceiling with an open lower end. The entire process container 1 is formed of, for example, quartz. A ceiling plate 2 formed of quartz is installed in the vicinity of an upper end in the process container 1, and the region below the ceiling plate 2 is sealed off. A metal manifold 3 formed in a shape of a cylindrical body is connected to the lower end opening of the process container 1 via a sealing member 4 such as an O-ring.

The manifold 3 supports the lower end of the process container 1, and a wafer boat 5 loaded with a number of sheets (e.g., 25 to 150 sheets) of semiconductor wafers (hereinafter referred to as “substrate W”) as substrates in multiple stages is inserted into the process container 1 from below the manifold 3. In this manner, a number of sheets of substrates W are accommodated substantially horizontally at intervals along a vertical direction in the process container 1. The wafer boat 5 is formed of, for example, quartz. The wafer boat 5 has three rods 6 (two are shown in FIG. 1), and a number of sheets of substrates W are supported by grooves (not shown) formed in the rods 6.

The wafer boat 5 is placed on a table 8 via a heat insulating tube 7 formed of quartz. The table 8 is supported on a rotating shaft 10 that passes through a metal (stainless steel) cover 9 that opens and closes the lower end opening of the manifold 3.

A magnetic fluid seal 11 is installed at a penetration portion of the rotating shaft 10 to thereby hermetically seal and rotatably support the rotating shaft 10. A sealing member 12 that maintains airtightness in the process container 1 is provided between a peripheral portion of the cover 9 and the lower end of the manifold 3.

The rotating shaft 10 is attached to a tip of an arm 13 supported by a elevating mechanism (not shown) such as, for example, a boat elevator, and the wafer boat 5 and the cover 9 move up and down integrally and are inserted into and separated from an inside of the process container 1. In addition, the table 8 may be fixed to the cover 9 such that the substrates W may be processed without rotating the wafer boat 5.

Further, the substrate processing apparatus 100 includes a gas supply 20 that supplies predetermined gases, such as a processing gas and a purge gas, into the process container 1.

The gas supply 20 includes gas supply pipes 21, 22, 23, and 24. The gas supply pipes 21 to 23 are formed of, for example, quartz, and pass through a side wall of the manifold 3 inward, bend upward, and extend vertically. In vertical portions of the gas supply pipes 21 to 23, a plurality of gas holes 21g to 23g are formed at predetermined intervals over a length in the vertical direction corresponding to a wafer support range of the wafer boat 5. The respective gas holes 21g to 23g discharge gases in a horizontal direction. The gas supply pipe 24 is formed of, for example, quartz, and is made of a short quartz pipe provided through the side wall of the manifold 3.

The gas supply pipe 21 is installed such that a vertical portion (a vertical portion where the gas hole 21g is formed) of the gas supply pipe 21 is provided in the process container 1. A processing gas is supplied to the gas supply pipe 21 from a gas supply source 22a via gas piping. The gas piping is provided with a flow controller 21b and an on-off valve 21c. As a result, the processing gas from the gas supply source 21a is supplied into the process container 1 via the gas piping and the gas supply pipe 21.

The gas supply pipe 22 is installed such that a vertical portion (a vertical portion where the gas hole 22g is formed) of the gas supply pipe 22 is provided in the process container 1. The processing gas is supplied to the gas supply pipe 22 from the gas supply source 22a via the gas piping. The gas piping is provided with a flow controller 22b and an on-off valve 22c. As a result, the processing gas from the gas supply source 22a is supplied into the process container 1 via the gas piping and the gas supply pipe 22.

The gas supply pipe 23 is installed such that a vertical portion (a vertical portion where the gas hole 23g is formed) of the gas supply pipe 23 is provided in the process container 1. The processing gas is supplied to the gas supply pipe 23 from the gas supply source 23a via the gas piping. The gas piping is provided with a flow controller 23b and an on-off valve 23c. As a result, the processing gas from the gas supply source 23a is supplied into the process container 1 via the gas piping and the gas supply pipe 23.

Here, the gas supply source 21a supplies a raw material gas containing Si. As the raw material gas, for example, an aminosilane-based gas such as diisopropylaminosilane (DIPAS) may be used. In addition, the raw material gas containing Si is not limited to organic aminosilane, but inorganic silanes, higher-order silanes, and silanols may also be used.

The gas supply source 22a supplies a shape control gas to be described later. As the shape control gas, for example, chlorine gas (Cl₂ gas) may be used. Further, as the shape control gas, F₂ or CIF₃ gas is also suitable and plasma to which RF is applied may also be used.

The gas supply source 23a supplies an oxidizing gas. As the oxidizing gas, for example, ozone gas (O₃ gas) may be used. In addition, as the oxidizing gas, O₂ or H₂O, H₂ and H₂ mixed gases, and the like, may be used, and it may be a radical by RF application or the like.

The gas supply pipe 24 is supplied with a purge gas from a purge gas supply source (not shown) via the gas piping. The gas piping (not shown) is provided with a flow controller (not shown) and an on-off valve (not shown). As a result, the purge gas from the purge gas supply source is supplied into the process container 1 via the gas piping and the gas supply pipe 24. As the purge gas, an inert gas such as, for example, argon (Ar) or nitrogen (N₂) may be used. Moreover, although the case where the purge gas is supplied into the process container 1 via the gas piping and the gas supply pipe 24 from the purge gas supply source has been described, the present disclosure is not limited thereto, and the purge gas may be supplied from any of the gas supply pipes 21, 22, and 23.

An exhaust port 40 configured to vacuum-exhaust an interior of the process container 1 is installed at a portion of a side wall of the process container 1 opposite a position where the gas supply pipes 21 to 23 are arranged. The exhaust port 40 is formed to be elongated vertically in correspondence to the wafer boat 5. An exhaust port cover member 41 formed in a U-shape in cross section so as to cover the exhaust port 40 is provided at a portion of the process container 1 corresponding to the exhaust port 40. The exhaust port cover member 41 extends upward along the side wall of the process container 1. An exhaust pipe 42 configured to exhaust the process container 1 through the exhaust port 40 is connected to a lower portion of the exhaust port cover member 41. A pressure control valve 43 that controls a pressure in the process container 1 and an exhaust apparatus 44 including a vacuum pump and the like are connected to the exhaust pipe 42, and the interior of the process container 1 is exhausted by the exhaust apparatus 44 through the exhaust pipe 42.

In addition, a heating mechanism 50 formed in a shape of a cylindrical body and configured to heat the process container 1 and the substrates W therein is provided to surround an outer periphery of the process container 1.

In addition, the substrate processing apparatus 100 includes a controller 60. The controller 60 controls, for example, an operation of each component of the substrate processing apparatus 100, for example, supply/stop of each gas by opening/closing the on-off valves 21c to 23c, control of the gas flow rate by the flow controllers 21b to 23b, and exhaust control by the exhaust apparatus 44. Moreover, the controller 60 controls the temperature of the substrates W by the heating mechanism 50, for example.

The controller 60 may be, for example, a computer or the like. Further, program of a computer that performs the operation of each component of the substrate processing apparatus 100 is stored in a storage medium. The storage medium may be, for example, a flexible disk, a compact disk, a hard disk, a flash memory, a DVD, or the like.

### Embedding of SiO₂ Film

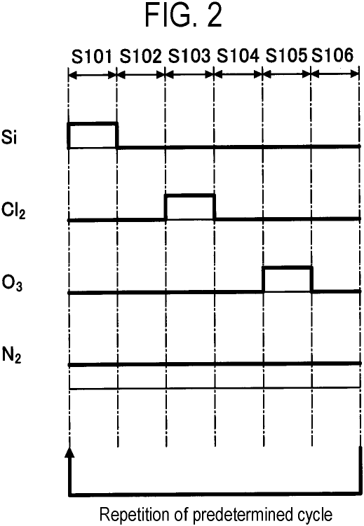

Next, an example of substrate processing by the substrate processing apparatus 100 shown in FIG. 1 will be described. FIG. 2 is an example of a time chart showing a film-forming process of a SiO₂ film by the substrate processing apparatus 100. Here, the substrate processing apparatus 100 forms the SiO₂ film on the substrate W and thereby embeds the SiO₂ film in a depression such as a trench formed on the surface of the substrate W.

The film-forming process shown in FIG. 2 is a process of embedding an SiO₂ film in a depression formed on the surface of the substrate W by repeating a cycle a predetermined number of times, the cycle including step S101 of supplying a raw material gas to the substrate W whose temperature has been adjusted to a predetermined temperature, step S102 of purging, step S103 of supplying a shape control gas, step S104 of purging, step S105 of supplying an oxidizing gas, and step S106 of purging. Further, FIG. 2 shows only one cycle. Moreover, in steps S101 to S106, N₂ gas that is the purge gas is constantly (continuously) supplied from the gas supply pipe 24 during the film-forming process.

Step S101 of supplying a raw material gas is a step of supplying the raw material gas containing Si (shown as Si in FIG. 2) into the process container 1. In step S101 of supplying the raw material gas, the raw material gas is supplied into the process container 1 from the gas supply source 21a via the gas supply pipe 21 by opening the on-off valve 21c.

Step S102 of purging is a step of purging the excess raw material gas or the like in the process container 1. In step S102 of purging, the supply of the raw material gas is stopped by closing the on-off valve 21c. As a result, the purge gas constantly supplied from the gas supply pipe 24 purges the excess raw material gas and the like in the process container 1.

Step S103 of supplying the shape control gas is a step of supplying the shape control gas into the process container 1. In step S103 of supplying the shape control gas, the shape control gas is supplied into the process container 1 from the gas supply source 22a via the gas supply pipe 22 by opening the on-off valve 22c.

Step S104 of purging is a step of purging the excess shape control gas or the like in the process container 1. In step S104 of purging, the supply of the shape control gas is stopped by closing the on-off valve 22c. As a result, the purge gas constantly supplied from the gas supply pipe 24 purges the excess shape control gas and the like in the process container 1.

Step S105 of supplying an oxidizing gas is a step of supplying the oxidizing gas into the process container 1. In step S105 of supplying the oxidizing gas, the oxidizing gas is supplied into the process container 1 from the gas supply source 21a via the gas supply pipe 21 by opening the on-off valve 21c.

Step S106 of purging is a step of purging the excess oxidizing gas or the like in the process container 1. In step S106 of purging, the supply of the oxidizing gas is stopped by closing the on-off valve 21c. As a result, the purge gas constantly supplied from the gas supply pipe 24 purges the excess oxidizing gas and the like in the process container 1.

By repeating the cycle described above, a SiO₂ film is formed on the substrate W, and the SiO₂ film is embedded in the depression of the surface of the substrate W.

Here, a preferable range of a film-forming condition in the film-forming process are presented below.

Substrate temperature: lower than 400° C. (more preferably, 300 to 350° C.)
Pressure: 0.1 to 9 Torr
Raw material gas flow rate: 50 to 1000 sccm
Shape control gas flow rate: 0.5 to 5000 sccm
Oxidizing gas flow rate: 500 to 10000 sccm
N₂ gas flow rate: 50 to 5000 sccm
Step S101 time: 2 to 30 seconds
Step S102 time: 2 to 30 seconds
Step S103 time: 0.5 to 10 seconds
Step S104 time: 2 to 30 seconds
Step S105 time: 10 to 120 seconds
Step S106 time: 2 to 60 seconds

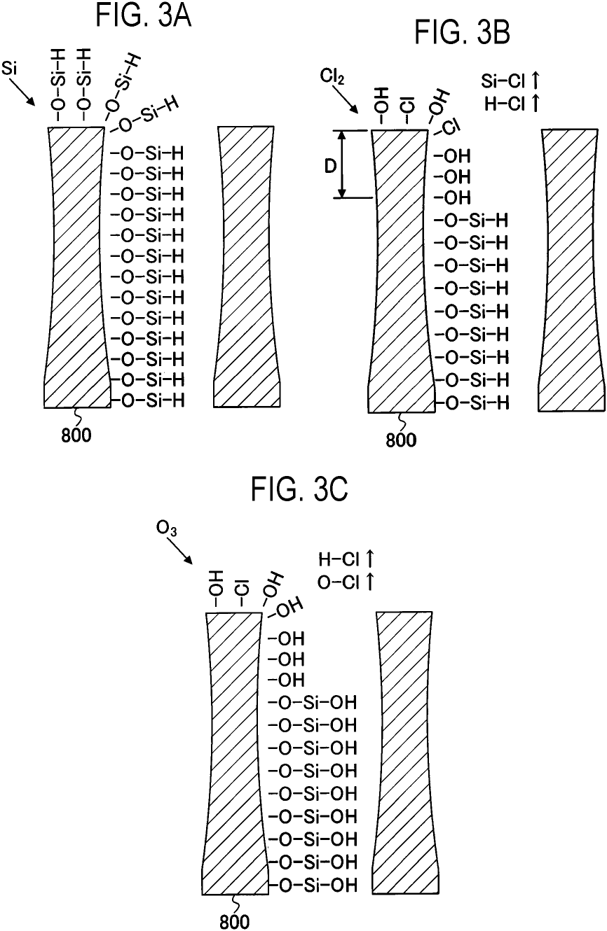

The film-forming process will be further described with reference to FIGS. 3A to 3C. FIGS. 3A to 3C are examples of schematic cross-sectional views of the substrate W in each step of the film-forming process.

Although not illustrated, the surface of the substrate W is terminated with OH groups before starting step S101 of supplying the raw material gas.

In step S101 of supplying the raw material gas, by supplying an aminosilane-based raw material gas (precursor gas) into the process container 1 and causing the substrates W in the process container 1 to be exposed to the raw material gas, an aminosilane-based precursor is adsorbed on the surfaces of the substrates W and thus, an adsorption layer of the precursor is formed on the surface of the substrates W. As shown in FIG. 3A, the surface of the substrate W becomes —O—Si—H due to the adsorption of the precursor.

In step S103 of supplying the shape control gas, by supplying Cl₂ gas (shape control gas) into the process container 1 and causing the substrates W in the process container 1 to be exposed to the Cl₂ gas, the aminosilane-based precursor adsorbed on the surfaces of the substrates W is etched. That is, at least a portion of the adsorption layer of the precursor formed on the surface of the substrates W is etched. Here, the etching with the Cl₂ gas is performed such that the reaction is limited in a depth direction D. Therefore, the adsorption layer is etched by the Cl₂ gas in the vicinity of the opening of the depression as shown in FIG. 3B. On the other hand, the adsorption layer is not etched in the vicinity of an inner side of the depression.

In step S105 of supplying the oxidizing gas, by supplying O₃ gas (oxidizing gas) into the process container 1 and causing the substrates W in the process container 1 to be exposed to O₃ gas such that the O₃ gas reacts with the aminosilane-based precursor adsorbed on the surface of the substrates W, thereby forming an SiO₂ film. That is, the O₃ gas reacts with the adsorption layer of the precursor formed on the surface of the substrates W, thereby forming the SiO₂ film. Here, the adsorption layer of the precursor is etched in the vicinity of the opening of the depression as shown in FIG. 3B described above. Therefore, the adsorption layer and the O₃ gas react with each other to form the SiO₂ film in the vicinity of the inner side of the depression, and the formation of the SiO₂ film is suppressed in the vicinity of the opening of the depression as shown in FIG. 3C.

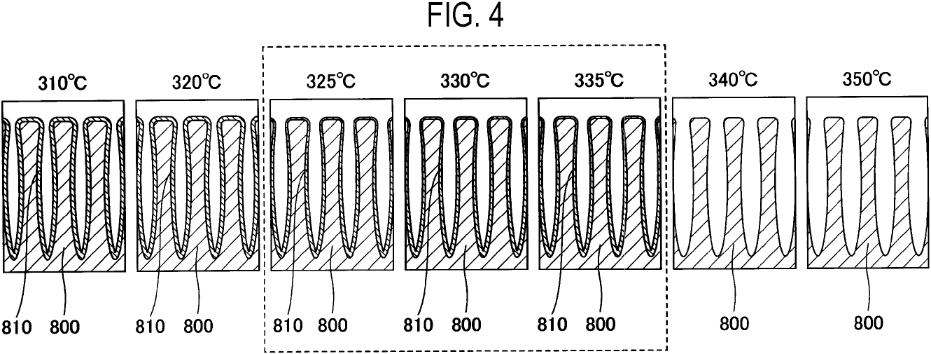

FIG. 4 is a cross-sectional view illustrating the relationship between the process temperature and the film shape of the SiO₂ film. Here, the SiO₂ film 810 was formed (embedded) in a depression structure 800 such as a trench of the substrate W under the process condition shown in FIG. 2 and described above, at the process temperatures of 310, 320, 325, 330, 335, 340, and 350° C.

As shown in FIG. 4, in the range of the process temperature of 310 to 320° C., a film having a uniform film formation amount (conformal film) near an inlet of the depression and near the inner side of the depression is formed.

As shown in FIG. 4, in the range of the process temperature of 325 to 335° C., the film formation amount (film formation rate) near the inlet of the depression is smaller than the film formation amount (film formation rate) near the inner side the depression. As a result, the SiO₂ film may be embedded so as to be formed in a V-shape such that a width of the SiO₂ film widens from the inner side toward the opening of the depression. Accordingly, it is possible to suppress the opening from being blocked by the SiO₂ film near the inlet of the depression before embedding the SiO₂ film on the inner side of the depression. In other words, it can be made into a shape that makes it easy to embed the film in the depression. As a result, it is possible to suppress generation of voids or seams.

On the other hand, in a case where the process temperature is 340° C. or higher, the film formation of the SiO₂ film is suppressed as shown in FIG. 4.

As described above, according to the substrate processing apparatus 100 in accordance with the present embodiment, the shape of the SiO₂ film to be formed in the depression of the substrate W can be controlled by controlling the temperature of the substrate W during the film-forming process. Specifically, by controlling the temperature of the substrate W during the film-forming process to 400° C. or lower, the shape of the SiO₂ film to be formed in the depression of the substrate W can be controlled. More preferably, by controlling the temperature of the substrate W during the film-forming process to be within the range of 300 to 350° C., the shape of the SiO₂ film to be formed in the depression of the substrate W can be controlled.

Specifically, by setting the temperature of the substrate W during the film-forming process to be within the range of 325 to 335° C., it is possible to form a SiO₂ film in which the film thickness near the opening of the depression is smaller than the film thickness near the inner side of the depression. In addition, by setting the temperature of the substrate W during the film-forming process to be within the range of 320° C. or lower, a conformal SiO₂ film can be formed in the depression. Furthermore, by setting the temperature of the substrate W during the film-forming process to be within the range of 340° C. or higher, it is possible to suppress the film formation of the SiO₂ film in the depression.

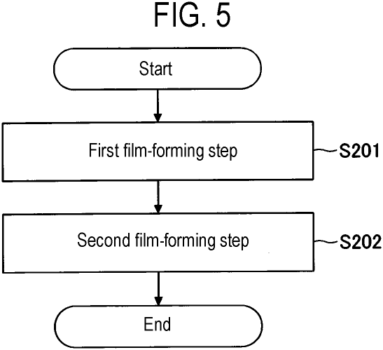

Next, an example of embedding the SiO₂ film by using the substrate processing apparatus 100 in accordance with the present embodiment will be further described with reference to FIG. 5.

FIG. 5 is a flowchart showing an example of embedding process of the SiO₂ film.

In a first film-forming step shown in step S201, the SiO₂ film is embedded such that the depression is V-shaped. Specifically, the film-forming process is performed on the substrate W within the range of the process temperature of 325 to 335° C. (first temperature).

In a second film-forming step shown in step S202, a conformal SiO₂ film is embedded. Specifically, for example, the film-forming process is performed on the substrate W within the range of the process temperature of 320° C. or lower (300 to 320° C.) (second temperature). Here, since the depression is formed in the V-shape in step S201, it is possible to suppress the occurrence of seams or voids when the depression is embedded with the conformal SiO₂ film. In addition, the second film-forming step S202 is not limited to this, and the steps of supplying and exhausting the shape control gas shown in S103 and S104 of FIG. 2 may be omitted. That is, it may be a process of forming the SiO₂ film by alternately repeating the supply and exhaust of the raw material gas (S101 and S102) and the supply and exhaust of the oxidizing gas (S105 and S106).

As described above, according to the process shown in FIG. 5, since the V shape is formed in the first film-forming step and the conformal film is formed along the V shape in the second film-forming step, a voidless SiO₂ film can be formed in the depression. In addition, since the conformal film is formed onto the V shape, an embedding speed can be improved as the film formation proceeds from the bottom surface and the side wall of the depression.

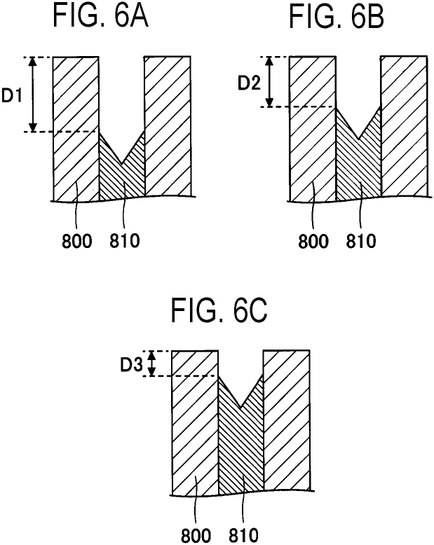

FIGS. 6A to 6C are schematic diagrams describing another embedding method of the SiO₂ film. In the verification of the present disclosure, changes in the coating property inside the trench are checked by vertical movement of the film-forming temperature. This indicates that the vertical movement of the generation position of the V shape can be controlled by the film-forming temperature. In a case where embedding with a V shape proceeds for a certain structure, a desired V-shaped film formation may not be obtained along with a change in an aspect ratio. In this case, the film-forming shape can be adjusted by interrupting the film-forming process for some time and changing the temperature of the substrate. This makes it possible to continue film-forming without taking out the substrate from the inside of the apparatus.

In FIG. 6A, a SiO₂ film is formed in the film-forming process shown in FIG. 2 at a process temperature T1 (a third temperature, for example, 335° C.). For example, in the initial state, the depression structure 800 such as a trench has a deeply depressed shape. Here, the SiO₂ film 810 is formed at the process temperature T1 that is higher than process temperatures T2 and T3, which will be described later, in a temperature range in which a film can be formed in a V shape (e.g., the range of 325 to 335° C. for forming a SiO₂ film in which the film thickness near the opening of the depression is smaller than the film thickness near the inner side of the depression). As a result, the SiO₂ film 810 can be embedded by forming the film preponderantly from the bottom of the depression structure 800 to a depth D1. When the aspect ratio of the depression structure 800 changes as the SiO₂ film 810 is embedded up to the depth D1, the etching becomes more excessive than the film formation, and thus, the embedding is suppressed as the film formation amount decreases.

Next, in FIG. 6B, a SiO₂ film is formed in the film-forming process shown in FIG. 2 at the process temperature T2 (a fourth temperature, for example, 330° C.). Here, the SiO₂ film 810 is formed at the process temperature T2 that is lower than the process temperature T1 in a temperature range in which a film can be formed in a V shape. As a result, the SiO₂ film 810 can be embedded by forming a film preponderantly from the bottom of the depression structure 800 to a depth D2. Further, since the SiO₂ film 810 has been embedded from the bottom of the depression structure 800 to the depth D1 at the process temperature T1, the embedding is performed from the depth D1 to the depth D2 at the process temperature T2. When the aspect ratio of the depression structure 800 changes as the SiO₂ film 810 is embedded up to the depth D2, the etching becomes more excessive than the film formation, and thus, the embedding is suppressed as the film formation amount decreases.

Next, in FIG. 6C, a SiO₂ film is formed in the film-forming process shown in FIG. 2 at the process temperature T3 (a fifth temperature, for example, 325° C.). Here, the SiO₂ film 810 is formed at the process temperature T3 that is lower than the process temperature T2 in a temperature range in which a film can be formed in a V shape. As a result, the SiO₂ film 810 can be embedded by forming a film preponderantly from the bottom of the depression structure 800 to a depth D3. Further, since the SiO₂ film 810 has been embedded from the bottom of the depression structure 800 to the depth D2 at the process temperature T2, the embedding is performed from the depth D2 to the depth D3 at the process temperature T3. When the aspect ratio of the depression structure 800 changes as the SiO₂ film 810 is embedded up to the depth D3, the etching becomes more excessive than the film formation, and thus, the embedding is suppressed as the film formation amount decreases.

By sequentially changing the process temperature in this manner, the SiO₂ film can be embedded from the bottom surface of the depression in a bottom-up fashion. As a result, since the SiO₂ film can be embedded in a bottom-up fashion even for depression shapes having a large aspect ratio, the occurrence of voids and seams can be suppressed. Further, by alternately performing the temperature control and film-forming process of the substrate, bottom-up embedding can be continuously realized as in-situ film-forming.

Although the substrate processing by the substrate processing apparatus 100 has been described above, the present disclosure is not limited to the above embodiments and the like, and various modifications and improvements can be made within the scope of the subject matter of the present disclosure set forth in the claims.

In addition, this application claims priority to Japanese Patent Application No. 2020-46631, filed on Mar. 17, 2020, the entire contents of which are incorporated herein by reference.

### EXPLANATION OF REFERENCE NUMERALS

W: substrate, 100: substrate processing apparatus, 1: process container, 2: ceiling plate, 20: gas supply, 21 to 24: gas supply pipes, 21a to 23a: gas supply sources, 44: exhaust apparatus, 50: heating mechanism, 60: controller

1-9. (canceled)

10. A substrate processing method comprising:
forming a silicon oxide film by performing a cycle a plurality of times, the cycle including:
forming an adsorption layer by supplying a silicon-containing gas to a substrate having a depression formed therein and causing the silicon-containing gas to be adsorbed on the substrate; etching at least a portion of the adsorption layer by supplying a shape control gas to the substrate; and supplying an oxygen-containing gas to the substrate and causing the oxygen-containing gas to react with the adsorption layer,
wherein a temperature of the substrate is 400° C. or lower.

11. The substrate processing method of claim 10, wherein the temperature of the substrate is 300° C. or higher and 350° C. or lower.

12. The substrate processing method of claim 11, wherein the silicon-containing gas is an aminosilane-based gas.

13. The substrate processing method of claim 12, wherein the oxygen-containing gas is ozone gas.

14. The substrate processing method of claim 13, wherein the shape control gas is chlorine gas.

15. The substrate processing method of claim 14, wherein in the performing the cycle the plurality of times, a shape of the silicon oxide film formed in the depression is controlled by controlling the temperature of the substrate.

16. The substrate processing method of claim 15, wherein the control of the shape of the silicon oxide film formed in the depression includes:
a first step of forming the silicon oxide film in which a film thickness near an opening of the depression is smaller than a film thickness near a bottom surface of the depression by controlling the temperature of the substrate to a first temperature; and
a second step of forming the silicon oxide film having a uniform film thickness by controlling the temperature of the substrate to a second temperature different from the first temperature.

17. The substrate processing method of claim 10, wherein the silicon-containing gas is an aminosilane-based gas.

18. The substrate processing method of claim 10, wherein the oxygen-containing gas is ozone gas.

19. The substrate processing method of claim 10, wherein the shape control gas is chlorine gas.

20. The substrate processing method of claim 10, wherein in the performing the cycle the plurality of times, a shape of the silicon oxide film formed in the depression is controlled by controlling the temperature of the substrate.

21. The substrate processing method of claim 20, wherein the control of the shape of the silicon oxide film formed in the depression includes:
a first step of forming the silicon oxide film in which a film thickness near an opening of the depression is smaller than a film thickness near a bottom surface of the depression by controlling the temperature of the substrate to a first temperature; and
a second step of forming the silicon oxide film having a uniform film thickness by controlling the temperature of the substrate to a second temperature different from the first temperature.

22. The substrate processing method of claim 20, wherein the control of the temperature of the substrate includes:
forming the silicon oxide film in which a film thickness near an opening of the depression is smaller than a film thickness near a bottom surface of the depression by controlling the temperature of the substrate to a third temperature;
forming the silicon oxide film in which the film thickness near the opening of the depression is smaller than the film thickness near the bottom surface of the depression by controlling the temperature of the substrate to a fourth temperature lower than the third temperature; and
forming the silicon oxide film in which the film thickness near the opening of the depression is smaller than the film thickness near the bottom surface of the depression by controlling the temperature of the substrate to a fifth temperature lower than the fourth temperature.

23. A substrate processing apparatus comprising:
a process container configured to accommodate a substrate having a depression formed therein;
a gas supply configured to supply gases to the process container; and
a controller,
wherein the controller is configured to form a silicon oxide film by repeating a cycle a plurality of times, the cycle including:
forming an adsorption layer by supplying a silicon-containing gas to the substrate and causing the silicon-containing gas to be adsorbed on the substrate;
etching at least a portion of the adsorption layer by supplying a shape control gas to the substrate; and
supplying an oxygen-containing gas to the substrate and causing the oxygen-containing gas to react with the adsorption layer, and
wherein a temperature of the substrate is 400° C. or lower.
